(19) United States
(12) Patent Application Publication
(10) Pub. No.: US 2021/0302508 A1
(43) Pub. Date: Sep. 30, 2021

(54) MAGNETIC SENSOR MODULE

(71) Applicant: Metrasens Limited, Worcestershire (GB)

(72) Inventor: Mark Nicholas KEENE, Worcestershire (GB)

(73) Assignee: Metrasens Limited, Worcestershire (GB)

(21) Appl. No.: 17/264,348

(22) PCT Filed: Aug. 1, 2019
(86) PCT No.: PCT/GB2019/052164

§ 371 Date: Jan. 29, 2021

(51) Int. Cl. G01R 33/02; G01R 33/00; G01R 33/022; G01V 3/08

(52) U.S. Cl. CPC G01R 33/0206; G01R 33/0076; G01V 3/081; G01R 33/022; G01R 33/0094

(57) ABSTRACT

A magnetic sensor module including: a plurality of sensor elements; a configurable processor configured to receive signals from the plurality of sensor elements and produce an output dependent on said signals; and an interface for communicating the output with an external system; where the configurable processor is configured to process the signals in a plurality of selectable modes.

The present invention relates to magnetic sensor modules with a configurable output, magnetic sensor modules that output processed data or raw data for external processing, and a network comprising said magnetic sensor modules.

Magnetic sensors are used in a growing number of applications. They are designed into products or scientific instruments, and configured specifically for the purposes of that product or instrument.

Ferromagnetic detection systems (FMDS) detect fluctuations in the ambient magnetic environment caused by ferromagnetic objects passing through a zone of sensitivity near to the system. They may be used to detect contraband in prisons, iron containing objects entering an MRI scanner room in a hospital, or weapons carried by the public.

There are many different types of magnetic sensor but the commonly used ones are fluxgates, amorphous magneto-resistive (AMR) sensor, and induction coils. The signal from the magnetic sensors (also known as magnetometers) normally requires processing before passing to a detection stage or a display. The processing depends upon the specific application as well as the sensor type, and is mainly associated with rejecting unwanted signals from the sensor's output.

For example, the Earth's field (approximately 56 micro-Tesla) is over a million times larger than the resolution of a standard commercial fluxgate (approximately 20 pico-Tesla) so, for detecting small changes in field, the Earth's field needs to be rejected. Likewise, the magnetic fields associated with mains electricity supplies at 50 or 60 Hz and their harmonics can be many thousands of times the sensor resolution and thus also need rejecting. In addition, the zone of sensitivity of the FMDS may need to be reduced in some applications to provide immunity from the effects of distant yet strong magnetic sources, such as traffic or machinery yet remain fully sensitive to nearby targets. Depending on the application of use the zone of sensitivity may be up to 20 m, up to 10 m, up to 2 m, up to 1 m, up to 30 cm, up to 10 cm.

There are known approaches used to minimise unwanted signals by signal processing in FMDS but they only work to a limited extent. There are also magnetically difficult environments where these are not effective enough, therefore FMDS cannot be used.

A series of magnetic sensors have been used to screen the public in order to identify those who are magnetically anomalous, i.e. indicating that they may be carrying contraband. However, such systems are not practical, for example lacking a means to robustly reject unwanted signals.

The present invention seeks to ameliorate or overcome some or all of the above-described issues.

According to a first aspect, there is provided a magnetic sensor module comprising:
a plurality of sensor elements;
a configurable processor configured to receive signals from the plurality of sensor elements and produce an output dependent on said signals; and
an interface for communicating the output with an external system;
   wherein the configurable processor is configured to process the signals in a plurality of selectable modes.

The first aspect therefore provides a magnetic sensor module with an adaptable configuration and that is therefore extremely versatile. Moreover, the ability to communicate with an external system allows additional versatility for use within various different types of systems.

The sensor element may each comprise a magnetic sensor.

The sensor elements may each comprise a vector magnetometer with multiple axes. There may be three axes and these axes may be orthogonal to one another. Each vector magnetometer may have three orthogonal axes. Each axis of one vector magnetometer may be aligned with a corresponding axis of one or more other vector magnetometers. The axes of each vector magnetometer may be aligned with the axes of the other vector magnetometers. The advantage of three orthogonal axes is that magnetic field incident upon them can be fully quantified. The advantage of these being aligned with other vector magnetometers is that the magnetic field gradient may be more accurately quantified.

Each vector magnetometer may include an amorphous magneto-resistive (AMR) sensor. These are advantageous because they are sensitive and cost effective. Cost effectiveness is important for the sensor module as they may need to be used in large numbers for some applications.

The plurality of sensor elements may be separated by a distance, commonly referred to as a baseline. The baseline may have a length of approximately 300 mm, which is a good balance between maximising the sensitivity without making the overall length too long to be practical. However, for some applications, other embodiments with different baselines may be useful. For example, up to 5 cm, up to, 10 cm, up to 30 cm up to 50 cm, up to 1 m.

Multiple magnetometers can, for example, be arranged as first or second order magnetic gradiometers. These may be formed by differencing signals from magnetometers; and/or a reference sensor may be employed to monitor external interference and compensate for this external interference (such as fluctuations in the local magnetic field caused by the use of nearby electronic equipment).

The processor may be configured to switch between the plurality of selectable modes dependent upon configuration data stored in the memory.

The processor may be configured to receive configuration data that is storable in the memory. The interface may be configured to receive configuration data that is storable in the memory. This is where an end user may simply reconfigure or repurpose the module without having to write processor code.

The magnetic sensor module may further comprise a memory. The memory may be internal to or be remotely connected to the magnetic sensor module. An internal memory may be used for holding alternative algorithms for the processor to use, and to store magnetic data for processing such as adaptive noise cancellation.

Additionally it may store historic data. The memory may be located in the cloud. The information may be securely stored, for example password protected, encrypted, and/or behind a firewall. The information may be stored on a distributed ledger.

The magnetic sensor module may include an interface that allows one or more of; means to output information, input information, access to the on-board memory, or to be the power supply input.

The interface may be configured to re-program the processor.

The magnetic sensor module may comprise an Ethernet connection, a wireless connection, and/or a standardised connector, for example, RS-232, CAN, or USB. The interface may comprise an Ethernet connection, a wireless connection, and/or a standardised connector, for example RS-232, CAN, or USB. These allow the modules to interface to pre-existing systems if necessary.

The sensor elements and/or sensor modules may comprise an identification signature, allowing the source of the signals and/or output to be determined.

The magnetic sensor module may comprise at least one switch for switching between the plurality of selectable modes. The switches may comprise software switches and/or hardware switches.

The magnetic sensor module may further comprise a housing which may be configured for providing environmental-proofing. The magnetic sensor module may further comprise a housing which may be configured for providing proofing from destructive human interaction, for example from people detained in a secure environment (e.g. a prisoner in a prison). The magnetic sensor module may further comprise a housing which may be configured for providing weather-proofing.

The magnetic sensor module may comprise a passive high-pass magnetic shield. The passive high-pass magnetic shield may comprise a metallic tube, which may be an aluminium or copper tube and may have a wall thickness of at least 12 mm. The passive high-pass magnetic shield can therefore prevent or limit interference from sources of magnetic fields. The protection may be suitable for protection from magnetic fields with a frequency of approximately 50 Hz or above, 60 Hz or above, or a range of approximately 50 to 60 Hz, for example. The shield may cover the sensor elements. The advantage of the passive shield is that the modules may be installed closer to sources of AC magnetic interference such as power lines, substations, or heavy electrical equipment. The passive high-pass magnetic shield may form at least a part of the housing. The magnetic sensor module may further comprise an RF (e.g. electromagnetic radiation in the frequency range 10⁴ and 10¹² Hz) shield. The RF shield may comprise a conductive shield. The RF shield may therefore provide protection from radio-frequency interference from electromagnetic sources. For example, commercial radio, TV, cell phone frequencies. The RF shield will exclude these from the module. The RF shield may form at least a part of the housing. In an embodiment the module is a discrete unit. In an embodiment the module is comprised within the housing. In an embodiment, the (longitudinal) baseline orientation of the module is the largest dimension of the module. In an embodiment the dimensions of the module orthogonal to the baseline are smaller than the baseline. In an embodiment, the module is portable; can be hand carried. In an embodiment, the module occupies a volume of less than 50, 40, 20, 10, 5, 3, 2, 1, 0.5 or 0.3 litres. In an embodiment, the module occupies a volume of at least 1, 0.5, 0.1, 0.01 or 0.001 litres.

The magnetic sensor module may comprise a printed circuit assembly, which supports the sensor elements and the processor. The sensor elements may be aligned with the printed circuit assembly. For example, where the sensor elements include vector magnetometers with three orthogonal axes, two of the three axes may be aligned with a plane of the printed circuit assembly. This has the advantage of keeping the module simple, inexpensive, reliably reproducible for manufacturing, and allows highly accurate placement and orientation of the sensors.

The output may comprise magnetic data for external processing. Magnetic data in this context may be considered to be, for example, the signals received direct from the sensor elements, or signals received from the sensor elements once they have been converted to digital signals and/or cleaned by conditioning electronics, or signals that have been processed together to produce an output, such as a combination of data from two or more sensor elements. These options add to the versatility of the modules for use in different applications.

The plurality of selectable modes may process the signals to output magnetic data in the form of at least one of:
a) independent gradient measurements;
b) total field measurements;
c) total field gradients;
d) directional gradients;
e) independent magnetic field measurements from each sensor; and
f) independent magnetic field measurements with the static DC components removed.

Gradient measurements may provide an indication of changes in magnetic field between two sensor elements. Total field measurements may provide an indication of an overall field strength at one or more sensor elements, or across a network of magnetic sensor modules. Directional gradients may provide an indication of changes in field strength in a specific direction. Different applications may need different magnetic information all of which may be obtained from the module with appropriate programming. Any or all of a) to f) may be calculated and output simultaneously.

The plurality of selectable modes may include processing of the signals using the following processes, where B1ₓ, B1_{y}, B1_{z} and B2ₓ, B2_{y}, B2_{z} are signals from three orthogonal axes of two respective sensor elements:
a) three independent gradient measurements
   (B1ₓ−B2ₓ), (B1_{y}−B2_{y}), and (B1_{z}−B2_{z})
b) two total field (scalar) measurements
   \sqrt{B1ₓ²+B1_{y}²+B1_{z}²} and \sqrt{B2ₓ²+B2_{y}²+B2_{z}²}
c) the total field gradient
   (\sqrt{B1ₓ²+B1_{y}²+B1_{z}²})−(\sqrt{B2ₓ²+B2_{y}²+B2_{z}²})
d) three directional gradients
   (|B1ₓ|−|B2ₓ|), (|B1_{y}|−|B2_{y}|), and (|B1_{z}|−|B2_{z}|)

These processes may be configured to function with a single sensor element with one axis, or additional sensor elements with one or more axes, as required.

The processor may be operable by a user, for switching between the selectable modes.

Alternatively, or additionally, the processor may be configured to automatically switch between the selectable modes, or to be reprogrammed to operate in different modes simultaneously depending upon the requirements of the application. This provides versatile deployment options.

The magnetic sensor module may comprise a self-test means for confirming proper operation of the magnetic sensor module. The processor may be configured to include a self-test mode for confirming proper operation of the magnetic sensor module.

A fault detected in the module may be reported to a maintenance alert system. The maintenance alert system may trigger an appropriate action in response to the detected fault. A network may comprise a maintenance alert system and a magnetic sensor module (and/or complex sensor configuration).

The signals may be processed by at least two processors, to check for consistency of the output. The second processor may be remotely connected to the fault containing magnetic sensor module. The second processor may be in another magnetic sensor module. The magnetic sensor modules may be connected in a complex sensor configuration or a network. A control processor may coordinate the signals and/or outputs. The control processor may be a standalone processor or a processor in one or more of the magnetic sensor modules.

In the case of a fault detected in a magnetic sensor, the faulty sensor could be isolated from the processor. In the case of a fault detected in a processor, the signals could be rerouted to a second processor for processing. The rerouting of the signals could be governed by a control sensor. In the case of a fault detected in the magnetic sensor module, the faulty magnetic sensor module could be restarted, restarted and retested, switched off, or put into a hibernation mode.

The magnetic sensor module may comprise an analog-to-digital converter configured to receive analog signals from the sensor elements and provide digital signals to the processor. The signals can then be processed digitally.

The magnetic sensor module may be further configured to receive power for powering the magnetic sensor module from a power source. The interface may be further configured to receive power for powering the magnetic sensor module from a power source.

The interface may output to an external system. The external system is any means that might make use of the output. It may include a user interface, a product for which the module is a component, a control processor that manages a network of modules, a unit that translates the output to another digital communication protocol or other communication means (e.g. for different transmission technologies), such as WiFi or RS-232. For example, a network of modules may interface to a security system such as a CCTV network, so when a detection occurs the appropriate CCTV image of the person causing the alert is captured and displayed to a security guard. To interface successfully, a translator unit may be needed to ensure the module and CCTV network can communicated, e.g. when the module and CCTV network are using different communication protocols.

The control processor may be governed, or partly governed, by a self-learning algorithm e.g. AI. In a system or network with a large number of modules it may be helpful to manage the modules and information these generate with the aid of machine learning. This may permit the system to be optimised for best performance, increasing the efficiently of information processing, lowering processing costs and/or making the information most useful to the end user.

The modules of the invention may find use in secure environments (like prisons, detention centres, police or military controlled zones), protected areas where metal or electronic equipment is not permitted (like governmental buildings, court rooms and board rooms), transport systems (like roads, ports, airports, train and underground networks), entertainment venues (like arenas, theatres, cinemas and stadiums), educational establishments (like schools and universities), religious establishments (like churches, synagogues and mosques), and/or any spaces where people are likely to be, gather, traverse, or trespass. The modules of the invention may also find application in controlling access to medical facilities like MRI facilities (e.g. a room containing a MRI machine).

Modules may be incorporated into access portals such as doors, gateways, archways or turnstiles. The modules may be placed in equipment, in free standing structures or incorporated into the infrastructure of buildings. Access to the interface may be by direct (e.g. buttons or touch screen) or indirect means (e.g. wireless access).

The module may comprise, and/or communicate with, a translator, where the translator converts the output which is in a first communication protocol into an output which is in a second communication protocol. The interface may comprise, and/or communicate with, a translator, where the translator converts the output which is in a first communication protocol into an output which is in a second communication protocol. For example, to translate an Ethernet communication protocol to RS-232 communication protocol. In certain applications, the invention may need to be incorporated into an existing communication infrastructure, or be connected to different communication infrastructures. The translator conveniently permits for example the modules of the invention to be integrated into these existing infrastructures, by conveniently converting/translating one communication protocol into another, and thereby permitting simple interoperability, with ease and while keeping the cost of manufacture low.

The output in the second communication protocol may be transmitted through wired, fibre-optical, wireless, or infrared means. The module may be configured to receive power for powering the magnetic sensor module from the translator, the translator configured to receive power from a power source. The interface may be configured to receive power for powering the magnetic sensor module from the translator, the translator configured to receive power from a power source. For example information and power may be provided by a Power over Ethernet (PoE) means. The advantage is that this simplifies the process of installation/integration of the modules into any system or apparatus (e.g. Plug and Play). This also dispenses with the need for an independent power source/line for each module. Upgrading the existing infrastructure may therefore not be required. It also would simplify the process of for example replacing a faulty unit. Reducing the number of connectors/ports on the interface also allows for a more compact design. These benefits cumulatively lower the cost of manufacture and of installation, in particular when a large number of modules are being manufactured and/or being installed, upgraded or replaced.

According to a second aspect, there is provided a magnetic sensor module comprising:
a plurality of sensor elements;
a processor configured to receive signals from the plurality of sensor elements and produce an output dependent on said signals; and
an interface for communicating the output with an external system;
wherein the output comprises magnetic data for external processing.

Having the configured processor provides for a simpler module arrangement, and hence a saving on manufacturing costs, and prevents/limits attempts to tamper with the module.

The module may be connectable to other magnetic sensor modules to form a complex module configuration. The interface may be connectable to other magnetic sensor modules to form a complex module configuration. The magnetic modules may be the same or different.

According to a third aspect, there is provided a complex module configuration wherein at least two magnetic modular sensors are connected, wherein the information outputs from the magnetic modular sensors are processed by the one or more processors in the magnetic modular sensor to produce a complex output. Modular magnetic sensors allow for a great saving in costs, in both manufacture and installation. With access to a simple, cheap, accurate and/or adaptable modular unit, many applications open up to the end user. Applications which may not have been considered previously, due to unacceptable cost and the complexity of any installation. Modular magnetic sensors therefore may also eliminate bespoke one-off assemblies, assemblies that may require detailed testing, validation and the associated teething problems. This is particularly the case where a system is large or is being upgraded, or expanded. In security applications, faithful and consistent results over a wide network would be an important consideration, and so a modular approach would be very beneficial in meeting that need.

According to a fourth aspect, there is provided a complex module configuration wherein at least two magnetic sensor modules of the first and/or second aspects are connected, and wherein the signals and/or outputs from the sensor modules are processed by one or more processors to produce a complex output.

A complex module configuration wherein the signals and/or outputs from the magnetic sensor modules may be processed by the one or more processors in the magnetic sensor modules to produce a complex output.

A complex module configuration wherein the signals and/or outputs from the magnetic sensor modules may be processed by one or more processors external to the sensor modules to produce a complex output.

According to a fifth aspect, there is provided a complex module configuration comprising:
a plurality of sensor modules according to the first and/or second aspects;
a command processor configured to receive signals from the plurality of sensor elements and/or outputs from the plurality of modules, and to produce a complex output dependent on said signals and/or outputs;
an interface for communicating the complex output with an external system;
wherein the command processor is configured to process the signals and/or outputs in a plurality of selectable modes.

A complex module configuration, where the command processor may be one or more of the processors in the plurality of sensor modules. A complex module configuration, where the command processor may be one or more processors internal or external to the plurality of sensor modules. A complex module configuration which may further comprise a memory. A complex module configuration where the memory may be internal or external to the plurality of sensor modules.

As such, a sensor module may connect to other modules to form complex sensor configurations. The sensor module may connect, via the interface, to other modules to form complex sensor configurations. The sensor module may connect, via the interface, to other identical modules to form complex sensor configurations. The connection may be a remote connection. The complex sensor configuration may comprise a control processor which can coordinate the connected sensor modules. Examples of complex sensor configurations include the nine-axis gradiometer, which use three orthogonal sensor modules as well as higher order magnetic gradiometers than the first order that is found in a single module.

According to a sixth aspect, there is provided a network comprising:
at least one magnetic sensor module or a complex module configuration; and
a central processor configured to receive outputs and/or complex outputs from the at least one magnetic sensor module and/or complex module configuration. The magnetic sensor module may be of the first and/or second aspects. The complex module configuration may be of the third, fourth and/or fifth aspects.

According to a seventh aspect, there is provided a network comprising:
a modular magnetic sensor, and/or a complex configuration of modular magnetic sensors; and
a processor configured to receive outputs and/or complex outputs from the modular magnetic sensors and/or complex configuration of modular magnetic sensors.

According to a seventh aspect, there is provided an apparatus comprising a magnetic sensor module, complex module configuration and/or network of any one of the preceding aspects.

According to an eighth aspect, there is provided the use of a magnetic sensor module, complex module configuration and/or network of any one of the preceding aspects. The use may be for detecting a magnetic signature indicative of a magnetisable object of interest passing through/by a zone policed by the magnetic sensor module, complex module configuration and/or network. An alert may be generated when a magnetic signature indicative of a magnetisable object of interest is detected. The alert may be discreet, being directed to only a responsible agency. The alert may generate an appropriate response from the responsible agency. The responsible agency may be for example a private security guard, CC-TV operator, prison guard, law enforcement body, national security force or a suitable algorithm. The use may be in a security application. The use may be for preventing unauthorised access to a medical facility like an MRI room, or to prevent tools or weapons being taken out of a certain location.

A network of sensors (sensor network) comprising one or more sensor modules (and/or complex sensor configurations) has many potential applications. Such networks potentially allow large areas to be monitored and/or controlled; even city or national wide networks are made possible. The modules of the invention make large sensor networks possible, because these modules are simple, reliable and cost effective to make. The assembly of a network is also greatly simplified by the use of standard modular parts, which excludes the need for bespoke manufacture and assembly. In that way, various contractors can simply incorporate the modules on a Plug and Play basis, without specialist insider knowledge. The modules of the invention also allow such a network to be readily expanded or modified if necessary, again without needing any specialist insider knowledge. The uniformity provided by use of standard modules also permits easy connectivity and interoperability.

Operational costs would also be reduced. With the aid of a central processor, for example, information from the sensors may be centrally processed, or the information may be directed to any idle processors, thereby getting the maximum efficiency out of the system. For example, a sensor network integrated into a broad transport network (which could even cover different time zones), could have idle processors in one area and overcapacity in other areas. In such a case, a central processor could distribute the process requirements over the whole network making use of the idle processors. Upgrades or software changes to sensor modules could be tested reliably and then rolled out effectively through the broader sensor network. These possibilities, and others that would occur to the skilled person, are made possible by the present invention.

In some cases, it may be useful to have a system comprising a magnetic sensor module (complex module configuration and/or network) of the invention, wherein a person of interest may only approach the zone policed by the sensor from a controlled direction (e.g. by means of a one way gate, or system to detect the direction of travel). In some cases, it may be useful to have an alert system comprising a magnetic sensor module (complex module configuration and/or network) of the invention, wherein the system has an alert suppression means, e.g. when an alert is generated together with a suppression event (e.g. a person is carrying a RF tag with an authorized signature; a person is approaching from an authorised direction; the system and/or module is placed in a non-alert mode, and/or the system is being run in a stealth mode). In some cases, it may be useful to have a system comprising a magnetic sensor module (complex module configuration and/or network) of the invention, which has means to capture video or image data of a person triggering an alert. Such image data could be cross referenced against a data set of reference images (e.g. images in a criminal or terrorist database) to see if a match is made; or the image could be directed to a responsible agency (e.g. the police). In some cases, it may be useful to have a system comprising a magnetic sensor module (complex module configuration and/or network) of the invention, which directs a person of interest to a controlled area by opening/closing/locking/unlocking choke points (e.g. allowing a person of interest to enter a train carriage and to direct the carriage to a secure location). In a network comprising multiple modules triggering multiple simultaneous alerts, it may be useful to have a system or algorithm which directs response resources of a responsible agency, like security personnel, to attend to the alert events in an effective manner.

In an embodiment, the module, pair of modules, complex module configuration, network, and/or method of using the same comprises means to allow the relative position of a metal object passing between two modules to be determined. Relative position can allow the object being detected to be readily found. Also, positional information can be used to mathematically calculate the magnetic moment (or proportional value thereof) of the object being detected, allowing for uniform sensing of objects, because magnetic moment is largely independent of sensor-object distance.

Specific, non-limiting, examples of the invention will now be described with reference to the accompanying drawings, in which:

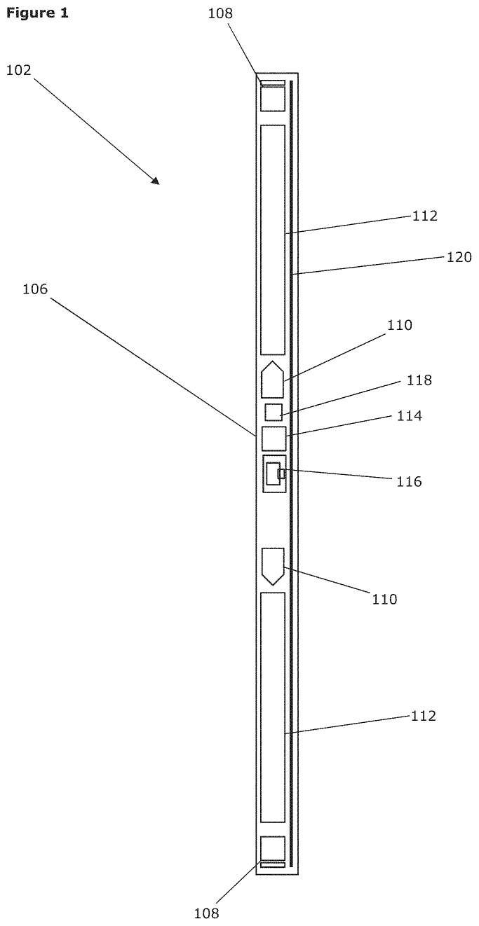

FIG. 1 is a schematic depiction of a printed circuit assembly of a magnetic sensor module in accordance with the invention;

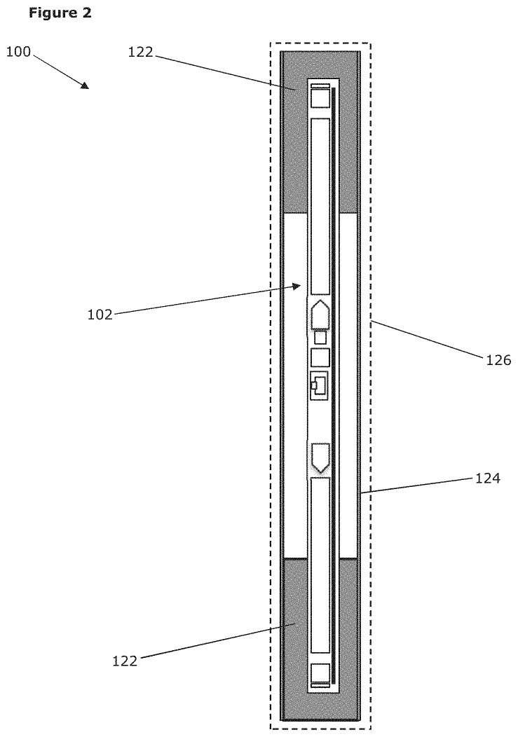

FIG. 2 is a schematic depiction of a magnetic sensor module in accordance with the invention, including the printed circuit assembly of FIG. 1;

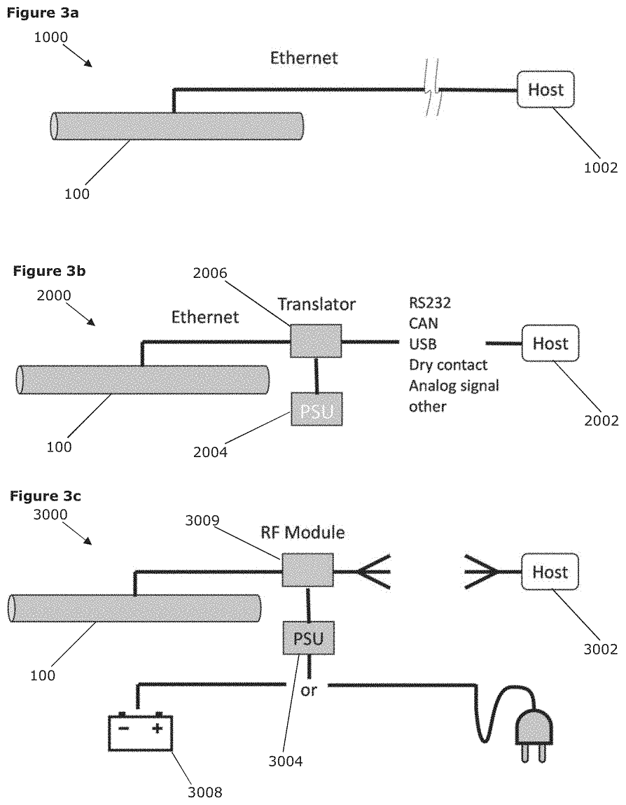

FIGS. 3a to 3c are schematic depictions of three examples for communicating with external systems in accordance with the invention;

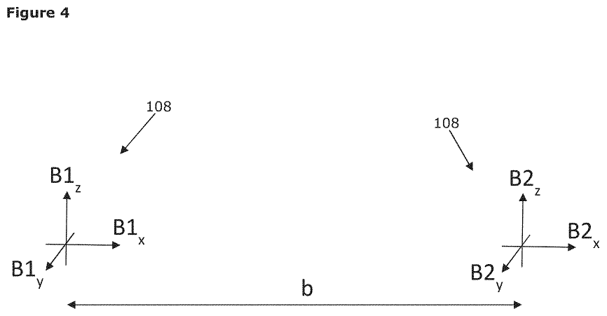

FIG. 4 is a diagrammatic view of two sensor elements separate by a baseline, suitable for three-dimensional magnetic sensing;

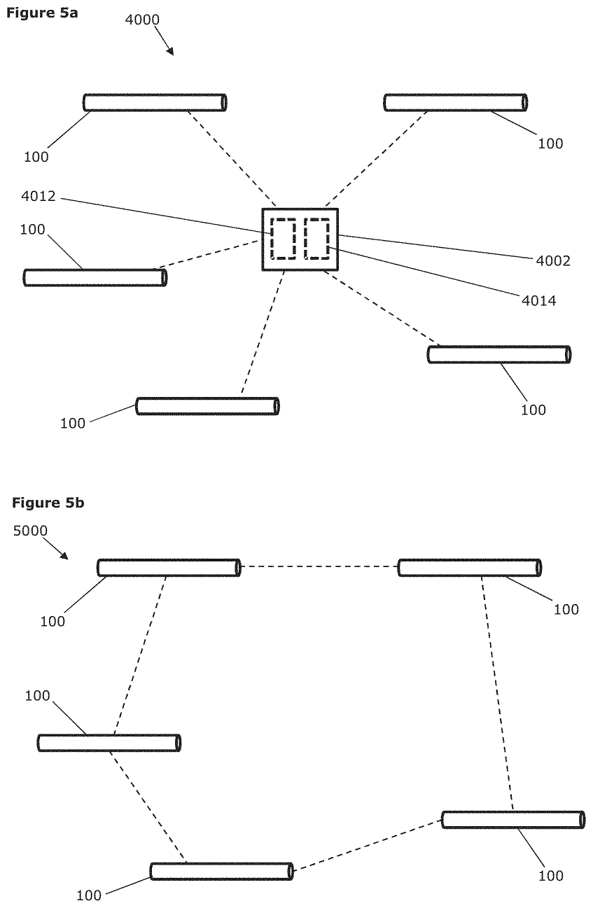

FIGS. 5a and 5b are schematic representations of two networks of magnetic sensor modules;

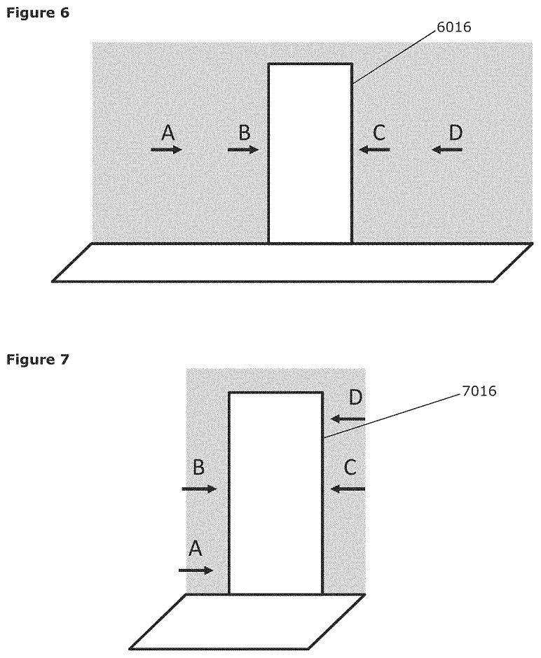

FIG. 6 is a first implementation of a network of magnetic sensor modules in relation to a doorway;

FIG. 7 is a second implementation of a network of magnetic sensor modules in relation to a doorway;

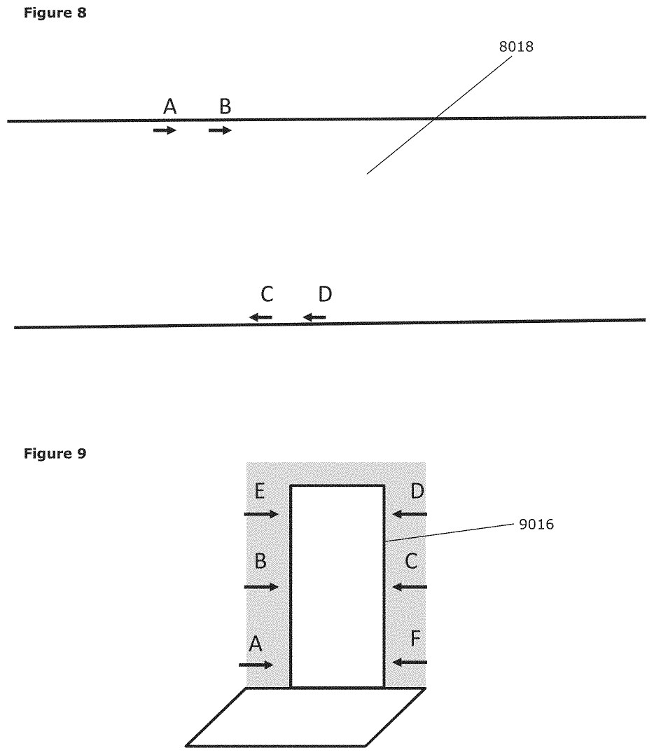

FIG. 8 is a first implementation of a network of magnetic sensor modules in relation to a corridor;

FIG. 9 is a third implementation of a network of magnetic sensor modules in relation to a doorway;

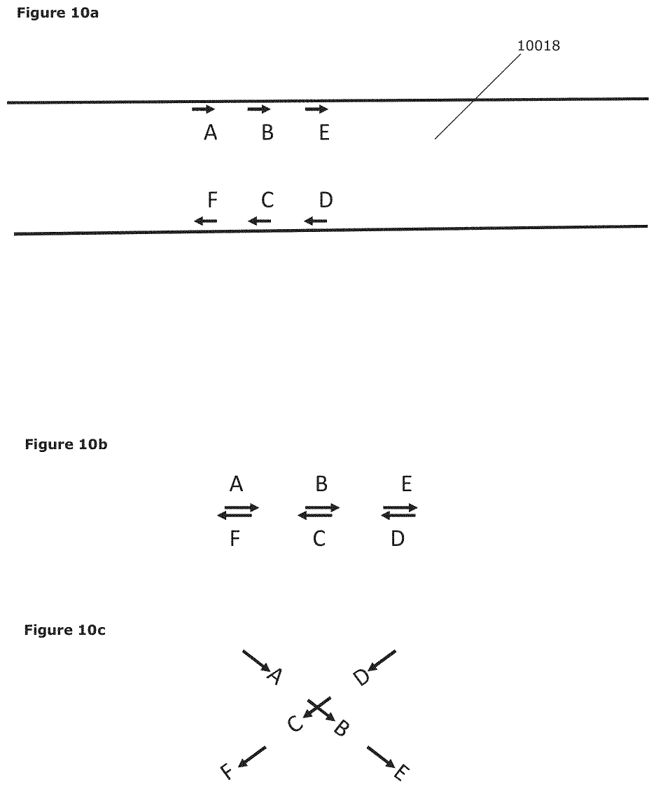

FIGS. 10a to 10c show two versions of a second implementation of a network of magnetic sensor modules in relation to a corridor;

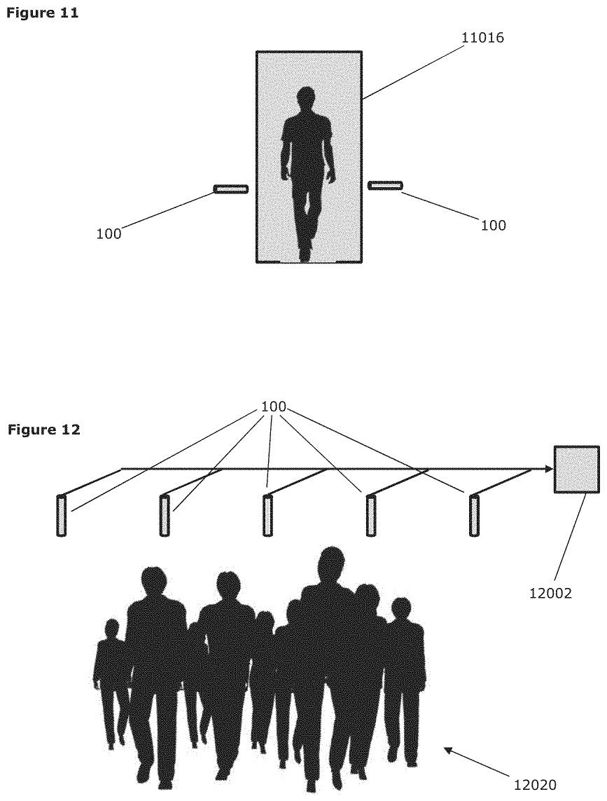

FIG. 11 shows a network of magnetic sensor modules implemented as a constricted flow monitor;

FIG. 12 shows a network of magnetic sensor modules implemented as an overhead free-flow monitor;

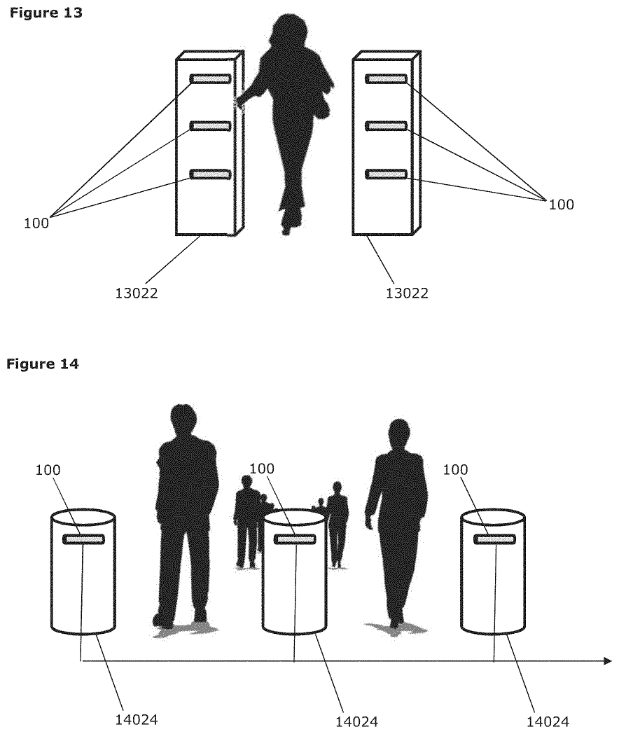

FIG. 13 shows a network of magnetic sensor modules implemented as a monitor for components in products;

FIG. 14 shows a network of magnetic sensor modules implemented as a monitor for free-flow through bollards; and

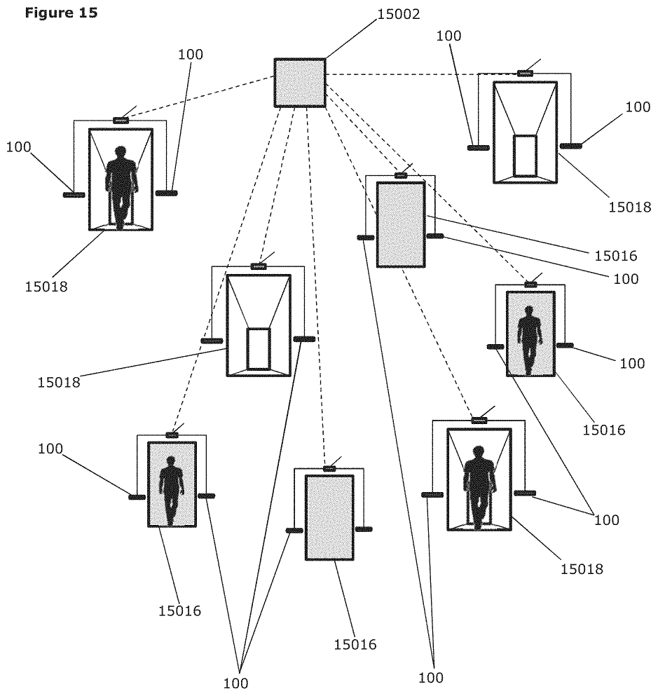

FIG. 15 shows a network of magnetic sensor modules implemented for networked monitoring of corridors and doorways in secure buildings.

Referring firstly to FIGS. 1 and 2, there are shown schematic depictions of an embodiment of a magnetic sensor module 100. The magnetic sensor module 100 comprises a printed circuit assembly (PCA) 102 and a surrounding shield 104. The PCA 102 is shown in isolation in FIG. 1.

The PCA 102 includes a printed circuit board (PCB) 106 to which two sensor elements 108 are mounted, separated by a baseline. By baseline it is meant that the sensor elements are separated by a predetermined distance. The sensor elements 108 are positioned towards opposing ends of the PCB 106. The sensor elements 108 of the present embodiment take the form of vector magnetometers with three orthogonal axes. A diagrammatic view of the sensor elements 108 and baseline is shown in FIG. 4, which is described in detail below. Due to the positioning of the sensor elements 108 on the PCB 106, the axes of the sensor elements 108 are aligned: one axis of each sensor element 108 is aligned with the length of the PCB 106; one axis of each sensor element 108 is aligned with the width of the PCB 106; and one axis of each sensor element 108 is aligned normal to the plane of the length and width of the PCB 106.

Each sensor element 108 outputs sensor signals indicative of a magnetic field detected within a detection zone of each sensor element 108. As the sensor elements 108 output analogue sensor signals, these sensor signals are transmitted to an analogue-to-digital converter (ADC) 110 associated with each of the sensor elements 108. Conditioning electronics 112 are also provided to process the sensor signals as well as to provide any necessary filtering and the interface to the ADCs 110. The ADCs 110 of the present embodiment measure the whole output range of the sensor elements 108 and also the self-generated noise of the sensor elements 108. The output of the ADCs 110 is passed to a processor 114.

A connector 116 is included, which receives signals from the processor 114 and provides an interface with external devices, such as an external processor, server, or additional magnetic sensor modules. Communication with the external devices is therefore two-way such that signals can be transmitted as well as received. The connector 116 also functions as a receiver for power from a power source.

Although depicted as a physical connector, the connector 116 may instead take the form of a wireless transceiver that allows wireless transmission of data. Where this is the case, a further physical connector may be provided for transmission of power to the magnetic sensor module, or a battery or power supply may be included within the magnetic sensor module. A battery allows a module to be placed in any desired location. In some cases, like a secure environment (e.g. a prison), access to electrical power sockets is extremely restricted, and so being battery powered allows the module to be installed anywhere. In addition, in the event of a power cut, or even a terrorist event leading to a break in the power supply, the module could be powered by a battery (or standby battery), allowing modules or systems incorporating these modules to continue to function.

Referring now to FIG. 4, each sensor element 108 is shown as a combination of its three axes B1ₓ, B1_{y}, B1_{z}, B2ₓ, B2_{y}, B2_{z}. The axes of each sensor element 108 are directed orthogonally to each other. A baseline, b, is shown which indicates the distance between the sensor elements 108. In the present embodiment, the baseline is 30 cm, in order to provide distance between the sensor elements 108 whilst retaining a portable size of magnetic sensor module 100. However, different baselines may be provided dependent on individual requirements of the magnetic sensor module 100. As can be seen, the baseline is aligned (baseline orientation) with the sensor axes B1ₓ and B2ₓ. Arrangement of the axes of the sensor element 108 in this way results in sensor signals that can be processed in different ways in order to provide various different useful outputs.

The processor 114 can therefore output at least the following different signals, dependent on the method of processing of the sensor signals:
three independent gradient measurements
   (B1ₓ−B2ₓ), (B1_{y}−B2_{y}), and (B1_{z}−B2_{z})
two total field (scalar) measurements
   \sqrt{B1ₓ²+B1ₓ²+B1_{z}²} and \sqrt{B2ₓ²+B2_{y}²+B2_{z}²}
the total field gradient
   (\sqrt{B1ₓ²+B1_{y}²+B1_{z}²})−(\sqrt{B2ₓ²+B2_{y}²+B2_{z}²})
three directional gradients
   (|B1ₓ|−|B2ₓ|), (|B1_{y}|−|B2_{y}|), and (|B1_{z}|−|B2_{z}|)

The above examples are some of the possible combinations of signals that can be computed by the processor 114. The processor 114 will be capable of outputting any combination of the sensor signals including these and any other non-listed combinations. Where a greater or lesser number of axes are included for each sensor element 108, the possibilities combinations of sensor signals will be affected as a result. Additionally, where a greater number of sensor elements 108 are provided in a magnetic sensor module 100, the possibilities for the processing of these signals will be greater. If only a single sensor element 108 is provided in a magnetic sensor module 100, the possibilities for processing of the signals will be less. Of course, if desired, the processor 114 may process the sensor signals in multiple different ways simultaneously, or in sequence.

Although the alignment of the axes in the present embodiment results in outputs that may be processed in the ways above, different alignments of axes of the sensor elements 108 does not preclude the same results being procured. However, the mathematics involved may be different in order to achieve the same results. As such, it is not intended to limit the invention to where the sensor elements 108 have aligned axes.

The processor 114 can output processed signals in real-time, or can use a memory 118 in order to collect and store data for output at intervals—regular, predefined or otherwise—or on demand, for example from a host server to which it is connected or upon connection of a different external device.

The processor 114 of the present embodiment can also perform a self-test function in order to output a signal indicative that it is functioning normally, this signal being receivable by connected external devices or being able to be logged in the memory 118. In the present embodiment, the self-test function comprises a track 120 on the PCB 106 that causes a defined response from the sensor elements 108 when a given current passes through the track 120. If the actual responses match the defined responses then a PASS will result. If one or both sensor elements 108 provide an incorrect response then a FAIL will result. The self-test function may be configured to operate at predefined times or at regular intervals. Failures may be reported to external devices. Alternatively, a connected external device may invoke the self-test function on demand.

Excessive exposure to power frequencies, for example by placement near power lines—can have negative effects on the ability of sensor elements 108 to function. For example, frequencies and harmonics sensed by a sensor element 108 in the vicinity of power lines may be large enough to use much of the sensor element's 108 range. In view of this, it may be desirable to eliminate these frequencies from the output of the present magnetic sensor module 100.

The shield 104 therefore provides a passive low-pass magnetic shield 122 in order to reduce the signals at power frequencies before they affect the sensor elements 108. This is provided by use of the skin effect. The magnetic shield 122 is found in two parts, each shielding one sensor element 108. However, in other embodiments, a single magnetic shield 122 may protect all sensor elements 108 in the magnetic sensor module 100.

There can also be interference from radio-frequency (RF) sources of interference. The magnetic sensor module 100 of the present embodiment therefore includes a shield 104 comprising both a high-pass magnetic shield 122 and an outer RF shield 124. The magnetic sensor module 100 is also encased in a further protective case 126 to protect the PBA 102 from the external environment.

The protective case 126 may therefore be constructed of a material that provides waterproofing and/or wind-proofing and/or insulation of the internals of the magnetic sensor module. Only materials that are not ferromagnetic in nature are suitable. Suitable materials may therefore include polymers such as plastics including acrylics, PVC, nylon, or other materials such as glass, aluminium and copper. The protective case 126 envelops the magnetic shield 122, RF shield 124, and PCA 102 in order to provide protection from weather, corrosion, etc. In addition to this, the protective case 126 can include fixture points to fix or mount the magnetic sensor module 100, if necessary.

Referring again to the magnetic shield 122, the properties are dictated by the materials used. The magnetic shield 122 of the present embodiment is formed of aluminium, which has a skin depth of 12 mm at 50 Hz. This means that a 50 Hz magnetic field is attenuated by 1/e (approximately 0.37) by a 12 mm aluminium magnetic shield, which equates to approximately −4.2 dB in amplitude. Attenuation increases with frequency and therefore higher frequencies are attenuated more. As such, the use of a magnetic shield 122 of 12 mm thick aluminium allows the sensor elements 108 to work in a mains electrical field at least twice as high as if no magnetic shield 122 were to be provided. Different materials may be used in place of aluminium, or with different thickness, depending on the specific attributes of the intended magnetic sensor module 100.

In general, the skin depth of a conductor can be calculated using the following equation:

$$δ = \sqrt{\frac{2 ρ}{{μ}_{0} 2 π f}} \approx 503 \sqrt{\frac{ρ}{f}}$$

where:
δ is the skin depth;
ρ is the resistivity;
μ₀ is the permeability of free space; and
ƒ is the frequency

In the present embodiment, where a 12 mm aluminium magnetic shield is provided, the amplitude attenuation is therefore as follows:

| | |
|---|---|
| f | Amplitude attenuation |

| (Hz) | (Decimal) | (Decibel) | |
|---|---|---|---|
| 0 | 0 | 0 | |
| 50 | 0.38 | −4.2 | dB |
| 100 | 0.25 | −6 | dB |
| 150 | 0.18 | −7.4 | dB |
| 200 | 0.14 | −8.5 | dB |
| 250 | 0.11 | −9.6 | dB |

The magnetic shield 122 is concentrated around the sensor elements 108 of the present embodiment and therefore resides towards the each end of the PCA 102. This is due to the fact that the sensor elements 108 require specific protection from external magnetic fields, these fields not having a substantial effect on the remainder of the PCA 102. In contrast, the RF shield 124 is provided along the length of the PCA 102 to avoid RF radiation on the reminder of PCA 102 which could otherwise be affected by RF.

The connector 116 of the magnetic sensor module 100 allows connection to a larger network of devices. Three types of network connection are shown in FIGS. 3a to 3b.

In FIG. 3a, a network 1000 is shown whereby a magnetic sensor module 100 is connected via Ethernet to a host server 1002. The host server 1002 is therefore capable of receiving signals output by the processor 114 through the connector 116. As well as data transmission, the Ethernet connection provides a power supply to the magnetic sensor module using Power over Ethernet (PoE). Such a PoE system may use a standard such as those of the Institute of Electrical and Electronics Engineers (IEEE): IEEE 802.3af-2003, IEEE 802.3at-2009 (PoE+), IEEE 802.3bu, and/or IEEE 802.3bt. Alternatively, an ad-hoc PoE system may be provided.

The network 2000 of FIG. 3b also includes a PoE connection to a magnetic sensor module 100, but a power supply unit 2004 is provided separate to the host server 2002. The power supply unit 2004 and host server 2002 are connected to the magnetic sensor module 100 by a translator 2006, which enables the power and data signals to be combined. The host server 2002 can communicate with the translator 2006 using any number of different transmission technologies such as, but not limited to, RS-232, CAN, USB, dry contact, analog signals, or others of which the skilled person will be aware.

In the network 3000 of FIG. 3c, a wireless link is used to communicate with the host 3002. Wireless linkages are well known in the art. The RF Module 3009 supplies the wireless interface between the Sensor module 100 and the host 300. The power supply unit 3004 of FIG. 3c receives power from a battery 3008 and/or a mains supply 3010.

FIGS. 5a and 5b show different embodiments of a network 4000, 5000 with multiple magnetic sensor modules 100. The network 4000 of FIG. 5a includes, but is not restricted to, five magnetic sensor modules 100, each of which communicates with a receiver 4012 of a central host server 4002. Thus, the host server 4002 can obtain data from each magnetic sensor module 100 in order to centrally process the data using a processor 4014 to obtain useful information. In FIG. 5b, a distributed network 5000 is shown, where five magnetic sensor modules 100 are interconnected such that they communicate with each other. Each magnetic sensor module 100 is connected to two other magnetic sensor modules 100. Processing of data can therefore be split between the processors 114 of the magnetic sensor modules 100 or data can be downloaded from the distributed network 5000 by an external device (not shown), such as a server or mobile device.

A combination of the networks 4000, 5000 of FIGS. 5a and 5b may be used or slightly different embodiments of the networks 4000, 5000 shown. For example, larger or smaller numbers of magnetic sensor modules 100 may be connected to one or more host servers, and interaction may be with only one or more host server, with other magnetic sensor modules 100, or a combination of the two.

When used in a network including multiple magnetic sensor modules, the above measurements can be used to obtain different results.

The directional measurement can be used in order to provide uniform sensing between a pair of magnetic sensor modules 100, such as by two magnetic sensor modules 100 arrange adjacent above a doorway. Such calculations can therefore effectively expand the baseline of a single magnetic sensor module 100.

The total field gradient measurement can be used to provide field mapping of areas within detection zones of multiple magnetic sensor modules 100.

In the network of FIG. 5a, processing of data provided from each magnetic sensor module 100 can be centrally processed by the processor of the host server 4002. The magnetic sensor modules 100 may therefore output raw data for processing by the host server 4002. By raw data, it is meant that data prior to substantial processing is transmitted to the server 4002, for example data relating to individual sensor element output before calculations using the outputs are combined with those of other sensor elements 108.

FIG. 6, FIG. 7, FIG. 8, FIG. 9, and FIGS. 10a to 10c each show more specific implementations of networked magnetic sensor modules 100. In each depiction, the arrows indicate the direction of alignment of an axis of one or more sensor element 108 associated with each magnetic sensor module 100. Letters A, B, C, D, E, and F each indicate a magnetic sensor module 100. Each implementation is discussed in terms of a positive detection of a ferromagnetic object resulting in an alarm. However, it should be understood that a positive detection need not result in a literal alarm but may result in any other response such as, but not limited to, the logging of a detection event, the triggering of an alarm or warning, or the alerting of a security guard. Moreover, it will be understood by the skilled person that any positive detection may be the result of a magnetic sensor module 100 outputting a signal higher than a threshold, in order to limit the occurrence of false positives or the detection of objects with a magnetic signature smaller than a predetermined size. The sensor may be calibrated so that only objects of the targeted size are detected. The calibration may be done or adjusted at the site, taking into account the magnetic signatures in the local environment. In each case, a host server is not depicted, but it will be understood that the processing of signals will be carried out in such a host server or another such processor.

FIGS. 6 and 7 show two different configurations of magnetic sensor modules 100 when used to detect ferromagnetic objects passing a doorway. In FIG. 6, the doorway 6016 is positioned in a planar wall so the magnetic sensor modules can be more spread out compared those in the constrained space of the doorway 7016 of FIG. 7. In each case, if |B−C|>|A−D|, an alarm can be raised. This is due to the fact that the difference in baseline of the two pairs of magnetic sensor modules indicates that a ferromagnetic object is passing through, or at least close to, the doorway 6016, 7016.

In FIG. 8, a similar system to those of FIGS. 6 and 7 is shown but in relation to a corridor 8018, which is shown in plan view. Again, if |B−C|>|A−D|, an alarm can be raised, for the same reason as the previous Figures.

FIG. 9 depicts a doorway 9016 protected by a total of six magnetic sensor modules. Three differences are therefore calculated. An alarm is raised if |B−C|>|A−D| and |B−C|>|E−F|. Such an arrangement therefore gives two different calculations, for the reduction of errors, due to the two pairs of magnetic sensor modules whose comparison results in a large effective baseline.

FIGS. 10a to 10c show an implementation of six magnetic sensor modules within a corridor 10018. FIG. 10a depicts the corridor 10018 in plan view, whilst FIGS. 10b and 10c show two different possibilities for alignment of the modules—however, in both possibilities the calculations are identical. In each case, an alarm is raised if |B−C|>|A−D| and |B−C|>|E−F|.

FIGS. 11 to 15 show further implementations of a network of magnetic sensor modules 100.

FIG. 11 shows how two magnetic sensor modules 100 can be arranged either side of a doorway 11016. Of course, such an arrangement is equally applicable to other types of restricted flow areas, such as corridors, tunnels, gates, etc. As shown, the two magnetic sensor modules 100 may be used as in the implementation of FIG. 6.

FIG. 12 shows how a series of five magnetic sensor modules 100 can be arranged to provide sensor coverage over a free-flow, for example a crowd of people 12020.

Each magnetic sensor module 100 sensor may operate as a single unit or adjacent units may act together to create a larger effective baseline for measurement. The five magnetic sensor modules 100 communicate with a host server 12002 that may be housed within a control room. By defining a distance above the crowd of people 12020, it is possible to provide a threshold for detection in order that, for example, only objects with a large ferromagnetic signature are detected by the network. Thus, an alarm is not raised for smaller, or innocuous, objects.

The arrangement of FIG. 13 shows how six magnetic sensor modules 100 may be arranged in order to sense ferromagnetic components of products, for example in order to prevent thefts. The two pillars 13022 are therefore arranged about a restricted flow area. The six magnetic sensor modules 100 may be used as in the implementation of FIG. 9.

FIG. 14 shows how magnetic sensor modules 100 can be arranged in bollards 14024 which may form an outer perimeter of a protected zone. For example, magnetic sensor modules 100 may be provided in bollards 14024 arranged around the outside of a football stadium. By using the signals from adjacent magnetic sensor modules 100, an alarm can be provided that allows direction of security personnel to a detection event, with the advantage that there is no overt restriction of flow through the perimeter. A single host server may monitor signals from all magnetic sensor modules in the perimeter.

FIG. 15 shows a series of magnetic sensor modules 100 associated with multiple doorways 15016 and corridors 15018. Signals from each pair of magnetic sensor modules 100 may by processed separately by a single host server 15002, the signals being transmitted in a wired or wireless manner. This has the advantage that it allows large-scale monitoring using a distributed system but without duplication of processing power.

1-50. (canceled)

51. A magnetic sensor module comprising:
a plurality of sensor elements;
a configurable processor configured to receive signals from the plurality of sensor elements and produce an output dependent on said signals; and
an interface for communicating the output with an external system;
wherein the configurable processor is configured to process the signals in a plurality of selectable modes.

52. The magnetic sensor module according to claim 51, wherein the sensor elements each comprise a magnetic sensor.

53. The magnetic sensor module according to claim 51, wherein the sensor elements each comprise a vector magnetometer with multiple axes.

54. The magnetic sensor module according to claim 53, wherein each vector magnetometer has three orthogonal axes.

55. The magnetic sensor module according to claim 54, wherein the axes of each vector magnetometer are aligned with the axes of the other vector magnetometers.

56. The magnetic sensor module according to claim 53, wherein each vector magnetometer includes an amorphous magneto-resistive sensor.

57. The magnetic sensor module according to claim 51, wherein the plurality of sensor elements are separated by a baseline.

58. The magnetic sensor module according claim 51, further comprising a memory.

59. The magnetic sensor module according to claim 58, wherein the processor is configured to switch between the plurality of selectable modes dependent upon configuration data stored in the memory.

60. The magnetic sensor module according to claim 59, wherein the interface is configured to receive configuration data that is storable in the memory.

61. The magnetic sensor module according to claim 60, wherein the interface is configured to re-program the processor.

62. The magnetic sensor module according to claim 51, wherein the interface comprises an Ethernet connection, wireless connection or a standardised connector.

63. The magnetic sensor module according to claim 51, wherein the sensor elements and/or sensor modules comprise an identification signature, allowing the source of the signals and/or output to be determined.

64. The magnetic sensor module according to claim 51, further comprising a printed circuit assembly, which supports the sensor elements and the processor.

65. The magnetic sensor module according to claim 64, wherein the sensor elements are aligned with the printed circuit assembly.

66. The magnetic sensor module according to claim 51, wherein the output comprises data for external processing.

67. The magnetic sensor module according to claim 66, wherein the plurality of selectable modes process the signals to output magnetic data in the form of at least one of:
a) independent gradient measurements;
b) total field measurements;
c) total field gradients;
d) directional gradients;
e) independent magnetic field measurements from each sensor; and
f) independent magnetic field measurements with the static DC components removed.

68. The magnetic sensor module according to claim 51, wherein the processor is operable by a user for switching between the selectable modes.

69. The magnetic sensor module according to claim 51, wherein the processor is configured to automatically switch between the selectable modes.

70. A complex module configuration comprising:
a plurality of sensor modules according to claim 51;
a command processor configured to receive signals from the plurality of sensor elements and/or outputs from the plurality of modules, and to produce a complex output dependent on said signals and/or outputs; and
an interface for communicating the complex output with an external system;
wherein the command processor is configured to process the signals and/or outputs in a plurality of selectable modes.

71. The complex module configuration of claim 70, wherein the command processor is one or more processors internal or external to the plurality of sensor modules.

72. A network comprising:
one or more magnetic sensor modules according to claim 51; and
a processor configured to receive outputs from the one or more magnetic sensors modules.
